(19) United States
(12) Patent Application Publication
(10) Pub. No.: US 2011/0201150 A1
(43) Pub. Date: Aug. 18, 2011

(54) Sputtering Apparatus, Thin-Film Forming Method, and Manufacturing Method for a Field Effect Transistor

(75) Inventors: Takaomi Kurata, Chiba (JP); Junya Kiyota, Chiba (JP); Makoto Arai, Chiba (JP); Yasuhiko Akamatsu, Chiba (JP); Satoru Ishibashi, Chiba (JP); Kazuya Saito, Chiba (JP)

(73) Assignee: ULVAC, INC., Kanagawa (JP)

(21) Appl. No.: 13/123,728

(22) PCT Filed: Oct. 9, 2009
(86) PCT No.: PCT/JP2009/005284

§ 371 Date: Apr. 12, 2011

(30) Foreign Application Priority Data
Oct. 16, 2008 (JP) 267925/2008

(51) Int. Cl. H01L 21/36; C23C 14/34; C23C 14/08

(52) U.S. Cl. 438/104; 204/298.12; 204/192.1; 257/E21.461

(57) ABSTRACT

[Object] To provide a sputtering apparatus, a thin-film forming method, and a manufacturing method for a field effect transistor, which are capable of reducing damage of a base layer.

[Solving Means] The sputtering apparatus 100 includes a conveying mechanism, a first target Tc1, a second target (Tc2 to Tc5), and a sputtering means. The conveying mechanism conveys a supporting portion, which is arranged in an inside of a vacuum chamber and supports a substrate, linearly along a conveying surface parallel to the surface to be processed of the substrate. The first target Tc1 is opposed to the conveying surface with a first space therebetween. The second target (Tc2 to Tc5) is arranged on a downstream side in a conveying direction of the substrate with respect to the first target Tc1, and is opposed to the conveying surface with a second space smaller than the first space therebetween. The sputtering means sputters each target. According to this sputtering apparatus 100, the damage received by the base layer is small, and hence it is possible to form a thin-film having good film-forming properties.

### TECHNICAL FIELD

The present invention relates to a sputtering apparatus for forming a thin-film on a substrate, a thin-film forming method using the same, and a manufacturing method for a field effect transistor.

### BACKGROUND ART

Conventionally, in a step of forming a thin-film on a substrate, there has been used a sputtering apparatus. The sputtering apparatus includes a sputtering target (hereinafter, abbreviated as “target”) arranged in the inside of the vacuum chamber and a plasma generation means for generating plasma in vicinity of the surface of the target. The sputtering apparatus subjects the surface of the target to sputtering using ions in the plasma so that particles (sputtered particles) sputtered from the target are deposited on the substrate. In this manner, a thin-film is formed (for example, see Patent Document 1).

### CITED DOCUMENT

### Patent Document

Patent Document 1: Japanese Patent Application Laid-open No. 2007-39712

### SUMMARY

### Problem to be solved by the Invention

A thin-film (hereinafter, also referred to as “sputtered thin-film”), which is formed by the sputtering method, has higher adhesion with respect to the substrate in comparison with a thin-film formed by a vacuum deposition method or the like because the sputtered particles incoming from the target are made incident on the surface of the substrate with high energy. Thus, a base layer (base film or base substrate) on which the sputtered thin-film is formed is easy to be greatly damaged due to collision of the incident sputtered particles. For example, when an active layer of a thin-film transistor is formed by the sputtering method, desired film properties may not be obtained due to the damage of the base layer.

In the above-mentioned circumstances, it is an object of the present invention to provide a sputtering apparatus, a thin-film forming method, and a manufacturing method for a field effect transistor, which are capable of reducing damage of a base layer.

### Means for solving the Problem

A sputtering apparatus according to an embodiment of the present invention is a sputtering apparatus for forming a thin-film on a surface to be processed of a substrate, and includes a vacuum chamber, a supporting portion, a conveying mechanism, a first target, a second target, and a sputtering means.

The vacuum chamber keeps a vacuum state.

The supporting portion is arranged in an inside of the vacuum chamber, and supports the substrate.

The conveying mechanism is arranged in the inside of the vacuum chamber, and linearly conveys the supporting portion along a conveying surface parallel to the surface to be processed.

The first target is opposed to the conveying surface with a first space therebetween.

The second target is arranged on a downstream side in a conveying direction of the substrate with respect to the first target, and is opposed to the conveying surface with a second space smaller than the first space therebetween.

The sputtering means sputters the first target and the second target.

A thin-film forming method according to an embodiment of the present invention includes arranging a substrate, which has a surface to be processed, in a vacuum chamber provided with a first target opposed to a conveying surface of the substrate with a first space therebetween and with a second target opposed to the conveying surface of the substrate with a second space smaller than the first space therebetween.

The substrate is conveyed from a first position to a second position.

In the first position, the surface to be processed is subjected to film formation using only sputtered particles obliquely emitted by sputtering the first target.

In the second position, the surface to be processed is subjected to film formation using sputtered particles perpendicularly emitted by sputtering the second target.

A manufacturing method for a field effect transistor according to an embodiment of the present invention includes forming a gate insulating film on a substrate.

A substrate is arranged in a vacuum chamber provided with a first target, which has In—Ga—Zn—O-based composition and is opposed to a conveying surface of the substrate with a first space therebetween, and with a second target, which has In—Ga—Zn—O-based composition and is opposed to the conveying surface of the substrate with a second space smaller than the first space therebetween.

The substrate is conveyed from a first position to a second position.

The surface to be processed is subjected, in the first position, to film formation using only sputtered particles obliquely emitted by sputtering the first target and is subjected, in the second position, the surface to be processed to film formation using sputtered particles perpendicularly emitted by sputtering the second target, to thereby form an active layer.

### BRIEF DESCRIPTION OF DRAWINGS

FIG. 1A plan view showing a vacuum processing apparatus according to a first embodiment.

FIG. 2 A plan view showing a holding mechanism.

FIG. 3 A plan view showing a first sputtering chamber.

FIG. 4 Schematic diagrams each showing a sputtering state.

FIG. 5 A flow chart showing a substrate-processing process.

FIG. 6 A view showing a sputtering apparatus used in an experiment.

FIG. 7 view showing a film thickness distribution of a thin-film obtained by the experiment.

FIG. 8 A view describing an incident angle of sputtered particles.

FIG. 9 A view showing a film-forming rate of the thin-film obtained by the experiment.

FIG. 10 A view showing ON-state current characteristics and OFF-state current characteristics when each of samples of thin-film transistors manufactured by the experiment is annealed at 200° C.

FIG. 11 A view showing ON-state current characteristics and OFF-state current characteristics when each of samples of thin-film transistors manufactured by the experiment is annealed at 400° C.

FIGS. 12 A plan view showing a first sputtering chamber according to a second embodiment.

### DETAILED DESCRIPTION

A sputtering apparatus according to an embodiment of the present invention is a sputtering apparatus for forming a thin-film on a surface to be processed of a substrate, and includes a vacuum chamber, a supporting portion, a conveying mechanism, a first target, a second target, and a sputtering means.

The vacuum chamber keeps a vacuum state.

The supporting portion is arranged in an inside of the vacuum chamber, and supports the substrate.

The conveying mechanism is arranged in the inside of the vacuum chamber, and linearly conveys the supporting portion along a conveying surface parallel to the surface to be processed.

The first target is opposed to the conveying surface with a first space therebetween.

The second target is arranged on a downstream side in a conveying direction of the substrate with respect to the first target, and is opposed to the conveying surface with a second space smaller than the first space therebetween.

The sputtering means sputters the first target and the second target.

The above-mentioned sputtering apparatus utilizes a space between the surface to be processed of the substrate and the target to control the incident energy (the incident energy per unit area) of the sputtered particles, and form a film. With this, the damage received by the base layer becomes smaller, and hence it is possible to form a thin-film having good film-forming properties.

The conveying mechanism may convey the substrate while sequentially passing through a fist position and a second position in the stated order, the first position may be a position in which only sputtered particles obliquely emitted from the first target arrive at the surface to be processed, and the second position may be a position in which sputtered particles perpendicularly emitted from the second target arrive at the surface to be processed.

The above-mentioned sputtering apparatus conveys the substrate from the first position to the second position while sputtering the substrate, and hence it is possible to gradually increase the incident energy.

A surface to be sputtered of the first target may be arranged in parallel to the conveying surface.

The above-mentioned sputtering apparatus is capable of setting an irradiation area of the sputtered particles emitted from the first target to be larger than an irradiation area of the sputtered particles emitted from the second target.

A surface to be sputtered of the first target may be arranged on a side of the second position.

The above-mentioned sputtering apparatus is capable of making the sputtered particles obliquely emitted from the first target incident on the surface to be processed of the substrate in a direction perpendicular to the surface to be processed of the substrate.

A thin-film forming method according to an embodiment of the present invention includes arranging a substrate, which has a surface to be processed, in a vacuum chamber provided with a first target opposed to a conveying surface of the substrate with a first space therebetween and with a second target opposed to the conveying surface of the substrate with a second space smaller than the first space therebetween.

The substrate is conveyed from a first position to a second position.

In the first position, the surface to be processed is subjected to film formation using only sputtered particles obliquely emitted by sputtering the first target.

In the second position, the surface to be processed is subjected to film formation using sputtered particles perpendicularly emitted by sputtering the second target.

A manufacturing method for a field effect transistor according to an embodiment of the present invention includes forming a gate insulating film on a substrate.

A substrate is arranged in a vacuum chamber provided with a first target, which has In—Ga—Zn—O-based composition and is opposed to a conveying surface of the substrate with a first space therebetween, and with a second target, which has In—Ga—Zn—O-based composition and is opposed to the conveying surface of the substrate with a second space smaller than the first space therebetween.

The substrate is conveyed from a first position to a second position.

The surface to be processed is subjected, in the first position, to film formation using only sputtered particles obliquely emitted by sputtering the first target and is subjected, in the second position, the surface to be processed to film formation using sputtered particles perpendicularly emitted by sputtering the second target, to thereby form an active layer.

Hereinafter, embodiments of the present invention will be described with reference to the drawings.

A vacuum processing apparatus 100 according to an embodiment of the present invention will be described.

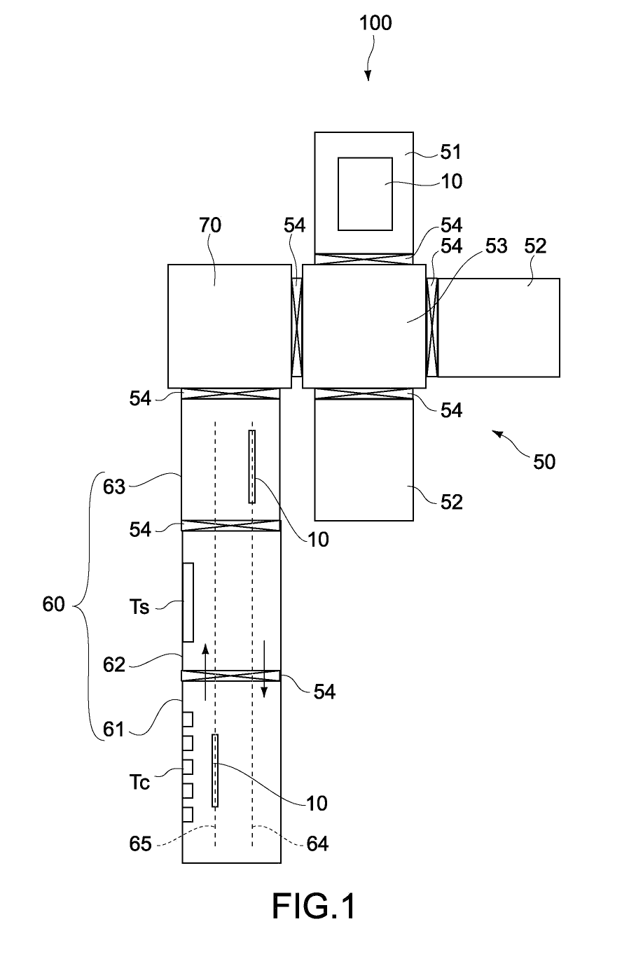

FIG. 1 is a schematic plan view showing the vacuum processing apparatus 100.

The vacuum processing apparatus 100 is an apparatus for processing a glass substrate (hereinafter, abbreviated as substrate) 10 to be used as a base material in a display, for example. Typically, the vacuum processing apparatus 100 is an apparatus responsible for a part of the manufacture of a field effect transistor having a so-called bottom gate type transistor structure.

The vacuum processing apparatus 100 includes a cluster type processing unit 50, an in-line type processing unit 60, and a posture changing chamber 70. Those chambers are formed in the inside of a single vacuum chamber or in the insides of combined vacuum chambers.

The cluster type processing unit 50 includes a plurality of horizontal type processing chambers. The plurality of horizontal type processing chambers process the substrate 10 in the state in which the substrate 10 is arranged substantially horizontally. Typically, the cluster type processing unit 50 includes a load lock chamber 51, a conveying chamber 53, and a plurality of CVD (Chemical Vapor Deposition) chambers 52.

The load lock chamber 51 switches between an atmospheric pressure state and a vacuum state, loads from the outside of the vacuum processing apparatus 100 the substrate 10, and unloads to the outside the substrate 10. The conveying chamber 53 includes a conveying robot (not shown). Each of the CVD chambers 52 is connected to the conveying chamber 53, and performs a CVD process with respect to the substrate 10. The conveying robot of the conveying chamber 53 carries the substrate 10 into the load lock chamber 51, each of the CVD chambers 52, and the posture changing chamber 70 to be described later. Further, the conveying robot of the conveying chamber 53 carries the substrate 10 out of each of the above-mentioned chambers.

In the CVD chambers 52, typically, a gate insulating film of the field effect transistor is formed.

It is possible to keep the conveying chamber 53 and the CVD chambers 52 under a predetermined degree of vacuum.

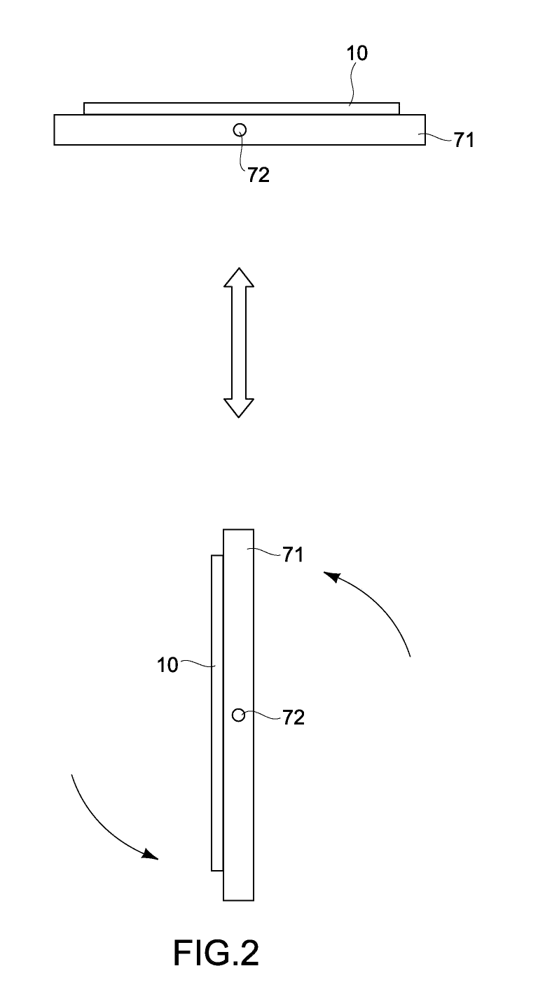

The posture changing chamber 70 changes the posture of the substrate 10 from the horizontal state to the vertical state and in turn, from the vertical state to the horizontal state. For example, as shown in FIG. 2, within the posture changing chamber 70, there is provided a holding mechanism 71 for holding the substrate 10. The holding mechanism 71 is configured to be rotatable about a rotating shaft 72. The holding mechanism 71 holds the substrate 10 by use of a mechanical chuck, a vacuum chuck, or the like. The posture changing chamber 70 can be kept under substantially the same degree of vacuum as the conveying chamber 53.

By driving a driving mechanism (not shown) connected to the both ends of the holding mechanism 71, the holding mechanism 71 may be rotated.

The cluster type processing unit 50 may be provided with a heating chamber and other chambers for performing other processes in addition to the CVD chambers 52 and the posture changing chamber 70, which are connected to the conveying chamber 53.

The in-line type processing unit 60 includes a first sputtering chamber 61 (vacuum chamber), a second sputtering chamber 62, and a buffer chamber 63, and processes the substrate 10 in the state in which the substrate 10 is oriented substantially upright.

In the first sputtering chamber 61, typically, as will be described later, a thin-film having In—Ga—Zn—O-based composition (hereinafter, abbreviated as IGZO film) is formed on the substrate 10. In the second sputtering chamber 62, a stopper layer film is formed on that IGZO film. The IGZO film constitutes an active layer for the field effect transistor. The stopper layer film functions as an etching protection layer for protecting a channel region of the IGZO film from etchant in a step of patterning a metal film constituting a source electrode and a drain electrode and in a step of etching and removing an unnecessary region of the IGZO film.

The first sputtering chamber 61 includes a plurality of sputtering cathodes Tc each including a target material for forming the IGZO film. The second sputtering chamber 62 includes a single sputtering cathode Ts including a target material for forming the stopper layer film.

The first sputtering chamber 61 is, as will be described later, configured as a sputtering apparatus using a fixed-type film-forming method. On the other hand, the second sputtering chamber 62 may be configured as a sputtering apparatus using the fixed-type film-forming method or as a sputtering apparatus using a passing-type film-forming method.

Within the first sputtering chamber 61, the second sputtering chamber 62, and the buffer chamber 63, there are prepared two conveying paths for the substrate 10, which are constituted of a forward path 64 and a return path 65, for example. Further, a supporting mechanism (not shown) is provided for supporting the substrate 10 in the state in which the substrate 10 is oriented upright or in the state in which the substrate 10 is slightly inclined from the upright state. The substrate 10 supported by the supporting mechanism is adapted to be conveyed through conveying rollers and a mechanism such as a rack-and-pinion mechanism, which are not shown.

Between the chambers, gate valves 54 are respectively provided. The gate valves 54 are controlled independently of each other to be opened and closed.

The buffer chamber 63 is connected between the posture changing chamber 70 and the second sputtering chamber 62. The buffer chamber 63 functions as a buffering region for pressurized atmosphere of the posture changing chamber 70 and pressurized atmosphere of the second sputtering chamber 62. For example, when the gate valve 54 between the posture changing chamber 70 and the buffer chamber 63 is opened, the degree of vacuum of the buffer chamber 63 is controlled to be substantially equal to the pressure within the posture changing chamber 70. Alternatively, when the gate valve 54 between the buffer chamber 63 and the second sputtering chamber 62 is opened, the degree of vacuum of the buffer chamber 61 is controlled to be substantially equal to the pressure within the second sputtering chamber 62.

In the CVD chambers 52, in some cases, specialty gas such as cleaning gas is used for cleaning those chambers. For example, in a case where the CVD chambers 52 are configured as vertical type apparatuses, there is a fear that the supporting mechanism, the conveying mechanism, and the like, as provided in the second sputtering chamber 62, which are peculiar to the vertical type processing apparatus, may be corroded due to the specialty gas, or the like. However, in the embodiment, the CVD chambers 52 are configured as the horizontal apparatuses, and hence the above-mentioned problem can be solved.

For example, in a case where the sputtering apparatus is configured as a horizontal apparatus, for example, when the target is arranged directly above the substrate, there is a fear that the target material adhering to the periphery of the target may drop on the substrate with a result that the substrate 10 may be contaminated. On the contrary, when the target is arranged under the base material, there is a fear that the target material adhering to a deposition preventing plate arranged in the periphery of the substrate may drop on an electrode with a result that the electrode may be contaminated. There is a fear that, due to the above-mentioned contaminations, an abnormal electrical discharge may occur during the sputtering process. However, the second sputtering chamber 62 is configured as a vertical type processing chamber, and hence the above-mentioned problem can be solved.

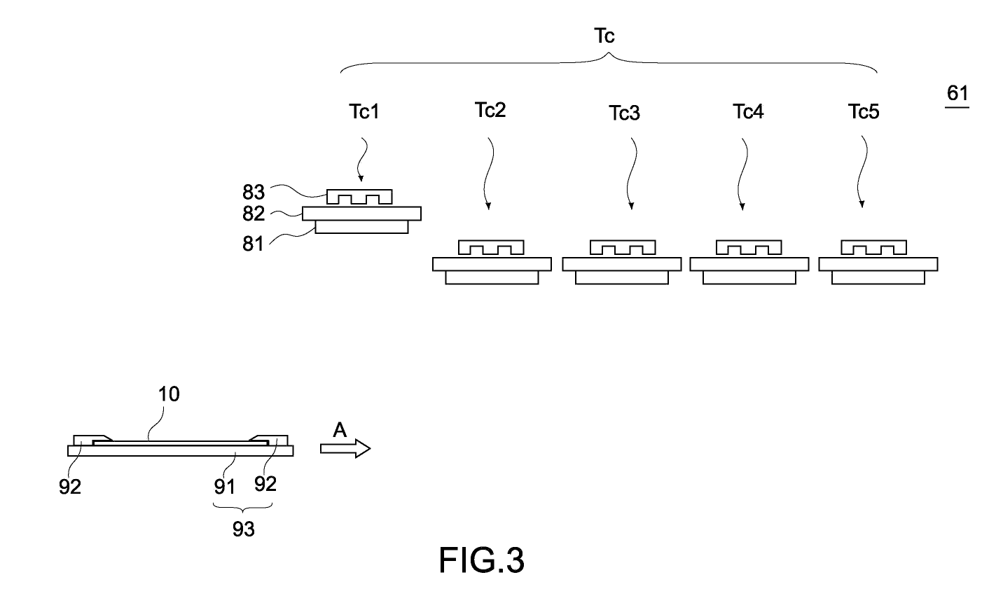

Next, the first sputtering chamber 61 will be described in detail. FIG. 3 is a schematic plan view showing the first sputtering chamber 61. The first sputtering chamber 61 is connected to a gas introduction line (not shown). Through the gas introduction line, to the first sputtering chamber 61, gas for sputtering such as argon and reactive gas such as oxygen are introduced.

The first sputtering chamber 61 includes sputtering cathodes Tc. The sputtering cathodes Tc are constituted of target portions Tc1, Tc2, Tc3, Tc4, and Tc5 each having the same configuration. The target portions Tc1, Tc2, Tc3, Tc4, and Tc5 are arranged in series in the stated order in a direction in which the substrate 10 is conveyed by a conveying mechanism to be described later so that a surface to be sputtered of each of those target portions is parallel to a conveying surface. It should be noted that the number of target portions is not limited to 5.

The target portion Tc1 positioned on the most upstream side in the conveying direction is arranged so that the target portion Tc1 has a larger space from the conveying surface of the conveying mechanism (or the surface to be processed of the substrate 10) in comparison with other target portions Tc2, Tc3, Tc4, and Tc5.

Each of the target portions Tc1 to Tc5 includes a target plate 81, a backing plate 82, and a magnet 83.

The target plate 81 is constituted of an ingot of film-forming material or a sintered body. In this embodiment, the target plate 81 is constituted of an alloy ingot or a sintered body material having In—Ga—Zn—O composition. The target plate 81 is attached so that the surface to be sputtered thereof is parallel to the surface to be processed of the substrate 10.

The backing plate 82 is configured as an electrode to be connected to an alternating-current power source (including high-frequency power source) or a direct-current power source, which are not shown. The backing plate 82 may include a cooling mechanism in which cooling medium such as cooling water is circulated. The backing plate 82 is attached to the back surface (the surface in opposite to the surface to be sputtered) of the target plate 81.

The magnet 83 is constituted of a combined body of a permanent magnet and a yoke. The magnet 83 forms a predetermined magnetic field 84 in the vicinity of a surface (surface to be sputtered) of the target plate 81. The magnet 83 is attached to the back side (a side in opposite to the target plate 81) of the backing plate 82.

The sputtering cathodes Tc configured in the above-mentioned manner generate plasma within the first sputtering chamber 61 by use of a plasma generation means including the power sources, the backing plate 82, the magnet 83, the gas introduction line, and the like. That is, when predetermined alternating-current power or predetermined direct-current power is applied on the backing plate 82, plasma of gas for sputtering is generated in the vicinity of the surface to be sputtered of the target plate 81. Then, by ions in the plasma, the target plate 81 is sputtered. Further, a high density plasma (magnetron discharge) is generated due to the magnetic field formed on the target surface by the magnet 83, and hence it is possible to obtain density distribution of plasma, which corresponds to magnetic field distribution.

Sputtered particles generated from the target plate 81 are emitted from the surface to be sputtered while being dispersed within a predetermined range. This range is controlled depending on formation conditions of plasma or the like. The sputtered particles include particles sputtered from the surface to be sputtered in a direction perpendicular to the surface to be sputtered, and particles sputtered from the surface of the target plate 81 in a direction oblique to the surface of the target plate 81. The sputtered particles sputtered from the target plate 81 of each of the target portions Tc1 to Tc5 are deposited on the surface to be processed of the substrate 10.

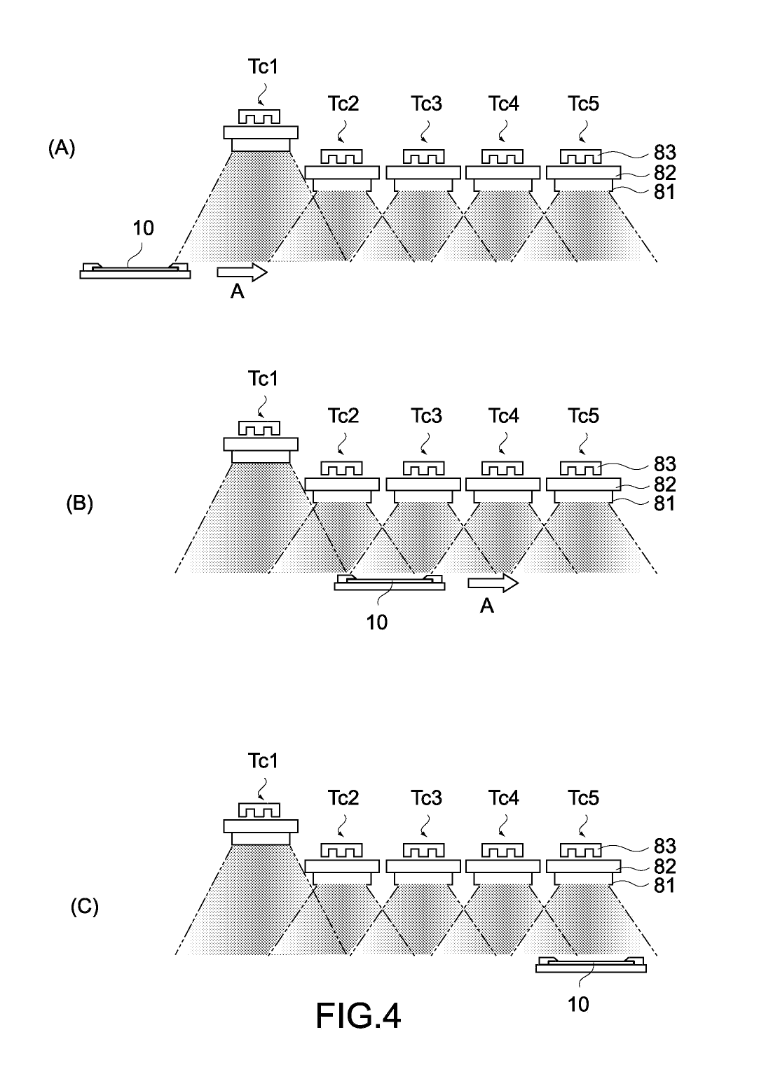

In the first sputtering chamber 61, the substrate 10 is arranged. The substrate 10 is supported by a supporting portion 93 provided with a supporting plate 91 and clamp mechanisms 92. The clamp mechanisms 92 hold the peripheral portion of the substrate 10 supported by the supporting region of the supporting plate 91. The supporting portion 93 is conveyed through the conveying mechanism (not shown) in one direction indicated by the arrow A in FIG. 3 and FIG. 4 along the conveying surface parallel to the surface to be processed of the substrate 10.

An arrangement relation between the target portions Tc1, Tc2, Tc3, Tc4, and Tc5 and the substrate 10 will be described.

The conveying mechanism conveys the supporting portion 93 in such a manner that the substrate 10 passes through a first position and a second position. The first position is located on an upstream side with respect to a position in which the target portion Tc1 and the substrate 10 are opposed (perpendicular) to each other. This position is a position in which only the sputtered particles obliquely emitted from the target portion Tc1 arrive at the surface to be processed of the substrate 10. The second position is a position in which the target portion on the most downstream side (in this embodiment, the target portion Tc5) and the substrate 10 are opposed to each other. This position is a position in which the sputtered particles perpendicularly emitted from the target portion Tc5 arrive at the surface to be processed of the substrate 10. It should be noted that, in the second position, the sputtered particles obliquely emitted from the adjacent target portion Tc4 may arrive. The conveying mechanism conveys the supporting portion 93 (the substrate 10) at least from the upstream with respect to the first position to the downstream with respect to the second position.

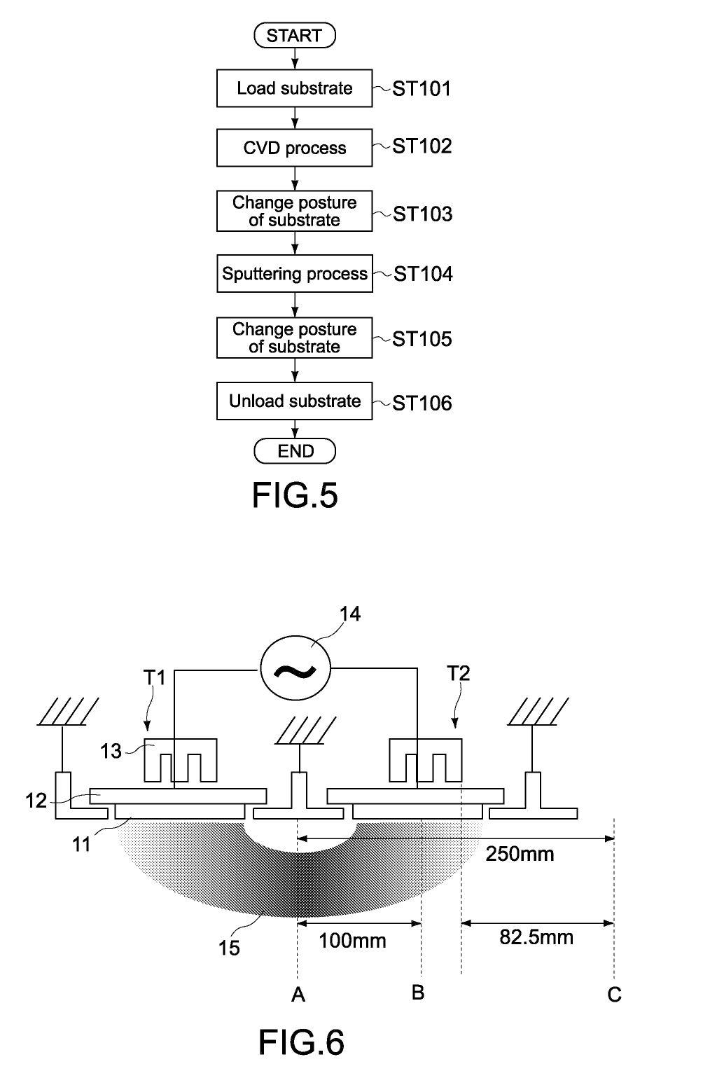

A processing order for the substrate 10 in the vacuum processing apparatus 100 configured in the above-mentioned manner will be described. FIG. 5 is a flow chart showing that order.

The conveying chamber 53, the CVD chambers 52, the posture changing chamber 70, the buffer chamber 63, the first sputtering chamber 61, and the second sputtering chamber 62 are each kept in a predetermined vacuum state. First, the substrate 10 is loaded in the load lock chamber 51 (Step 101). After that, the substrate 10 is conveyed through the conveying chamber 53 into the CVD chambers 52, and a predetermined film, for example, a gate insulating film is formed on the substrate 10 by the CVD process (Step 102). After the CVD process, the substrate 10 is conveyed through the conveying chamber 53 into the posture changing chamber 70, and the posture of the substrate 10 is changed from the horizontal posture to the vertical posture (Step 103).

The substrate 10 in the vertical posture is conveyed through the buffer chamber 63 into the sputtering chamber, and is further conveyed through the forward path 64 up to the end of the first sputtering chamber 61. After that, the substrate 10 takes the return path 65, is stopped within the first sputtering chamber 61, and is subjected to the sputtering process in the following manner. Thus, for example, an IGZO film is formed on the surface of the substrate 10 (Step 104).

With reference to FIG. 3, the substrate 10 is conveyed by the supporting mechanism within the first sputtering chamber 61, and is stopped at the first position or a position on the upstream side with respect to the first position. In the first sputtering chamber 61, sputtering gas (argon gas and oxygen gas or the like) at a predetermined flow rate is introduced. As described above, when the electric field and the magnetic field are applied to the sputtering gas and plasma is generated, sputtering of each of the target portions Tc1, Tc2, Tc3, Tc4, and Tc5 is started. It should be noted that, sputtering of all of the target portions Tc1, Tc2, Tc3, Tc4, and Tc5 may not be started before the conveyance of the substrate 10 is started, and the sputtering of each of those target portions may be started along the conveying direction A of the substrate in sequence along with the proceeding of the conveyance.

FIG. 4 are views each showing a sputtering state.

FIG. 4(A) shows a state in which the substrate 10 is positioned in the first position, FIG. 4(C) shows a state in which the substrate 10 is positioned in the second position, and FIG. 4(B) shows a state in which the substrate 10 is positioned in a middle position between the first position and the second position. The sputtering proceeds in the order of FIGS. 4(A), 4(B), and 4(C).

As shown in those figures, the substrate 10 (the supporting portion 93) is subjected to the film formation while being conveyed by the conveying mechanism. It should be noted that the conveyance may be continuous or may be stepwise (repeating conveyance and stop). [0054] In the start phase of the sputtering shown in FIG. 4(A), the substrate 10 has been conveyed to the first position. In this position, only the sputtered particles obliquely emitted from the surface to be sputtered of the target portion Tc1 arrive at the surface to be processed of the substrate 10. The substrate 10 is not opposed to the target portion Tc1, and hence the sputtered particles emitted in the direction perpendicular to the surface to be sputtered cannot arrive at the surface to be processed. As described above, the target portion Tc1 has a larger space with respect to the substrate 10 in comparison with other target portions Tc2, Tc3, Tc4, and Tc5, and hence the sputtered particles emitted in the oblique direction arrive at the surface to be processed while being dispersed more widely. With this, in comparison with the case where other target portions Tc2, Tc3, Tc4, and Tc5 are sputtered, a film-forming area is larger in the case of the target portion Tc1. As a result, incident energy of the sputtered particles with respect to the surface to be processed per unit area is decreased in the case of the target portion Tc1.

After the surface to be processed is subjected to the film formation using the sputtered particles obliquely emitted from the target portion Tc1, the surface to be processed becomes opposed to the target portion Tc1 along with the conveyance, and is subjected to the film formation using the sputtered particles perpendicularly emitted from the target portion Tc1 and the sputtered particles obliquely emitted from the target portion Tc2.

As shown in FIG. 4(B), the substrate 10 is further conveyed, and is subjected to the film formation using the sputtered particles emitted respectively from other target portions Tc2, Tc3, Tc4, and Tc5. The substrate 10 is, in advance, subjected to the film formation by the target portion Tc1 having the larger space with respect to the surface to be processed and having the larger film-forming area. Thus, the sputtered particles emitted from the target portions Tc2, Tc3, Tc4, and Tc5 each having a smaller space and larger incident energy cannot arrive directly at the (new) surface to be processed on which no film is formed.

As shown in FIG. 4(C), the substrate 10 is conveyed up to the second position being the position in which the substrate 10 is opposed to the target portion Tc 5, and the film formation is terminated. It should be noted that although the conveyance may be performed until the substrate 10 is moved on the downstream side with respect to the second position, on the downstream side with respect to the second position, only the sputtered particles obliquely emitted from the target portion Tc5 arrive at the surface to be processed, and are deposited on the most upper layer of the already manufactured thin-film. In a case where the incident angle of the sputtered particles with respect to the surface to be processed affects the film properties of the formed thin-film, the sputtering may be terminated in a phase in which the substrate is conveyed up to the second position.

As described above, the surface to be processed of the substrate 10 is first subjected to the film formation using the sputtered particles emitted from the target portion Tc1, and then is subjected to the film formation using the sputtered particles emitted from the target portions Tc2, Tc3, Tc4, and Tc5. The sputtered particles emitted from the target portion Tc1 having the larger space with respect to the surface to be processed are dispersed more widely in comparison with the sputtered particles emitted from other target portions Tc2, Tc3, Tc4, and Tc5 each having the smaller space with respect to the surface to be processed. With this, in the case of the target portion Tc1, the incident energy per unit area received by the surface to be processed becomes also smaller, and the damage received by the surface to be processed is also smaller. On the other hand, the number of the sputtered particles per unit area, which are emitted from the target portion Tc1, is smaller, and hence the film-forming speed is lower. However, due to the sputtered particles emitted from the following target portions Tc2, Tc3, Tc4, and Tc5, it is possible to form a film without greatly reducing the resulting film-forming speed. The sputtered particles emitted from the target portions Tc2, Tc3, Tc4, and Tc5 arrive only at the region in which the film is already formed on the surface to be processed. Therefore, the already formed film serves as a buffering material, and hence the surface to be processed does not receive the damage.

The substrate 10 on which the IGZO film is formed within the first sputtering chamber 61 is conveyed to the second sputtering chamber 62 together with the supporting plate 91. In the second sputtering chamber 62, a stopper layer made of a silicon oxide film, for example, is formed on the surface of the substrate 10 (Step 104).

For the film-forming process in the second sputtering chamber 62, similarly to the film-forming process in the first sputtering chamber 61, the fixed-type film-forming method of forming a film with the substrate 10 being stabilized within the second sputtering chamber 62 is employed. The present invention is not limited thereto, the passing-type film-forming method of forming a film with the substrate 10 being passed through the second sputtering chamber 62 may be employed.

After the sputtering process, the substrate 10 is conveyed through the buffer chamber 61 into the posture changing chamber 70, and the posture of the substrate 10 is changed from the vertical posture to the horizontal posture (Step 105). After that, the substrate 10 is unloaded through the conveying chamber 53 and the load lock chamber 51 to the outside of the vacuum processing apparatus 100 (Step 106).

As described above, according to this embodiment, in the inside of one vacuum processing apparatus 100, it is possible to consistently perform CVD deposition and sputtering deposition without exposing the substrate 10 to the atmosphere. Thus, it is possible to achieve an increase of the productivity. Further, it is possible to prevent moisture and dust existing within the atmosphere from adhering to the substrate 10. Therefore, it is also possible to achieve an increase of the film quality.

Further, as described above, by forming an initial IGZO film in a state in which the incident energy is low, it is possible to reduce the damage of the gate insulating film being the base layer, and hence it is possible to manufacture a field-effect thin-film transistor having high properties.

### Second Embodiment

A vacuum processing apparatus according to a second embodiment will be described.

In the following, the description of parts having the same configuration as the configuration of the above-mentioned embodiment will be simplified.

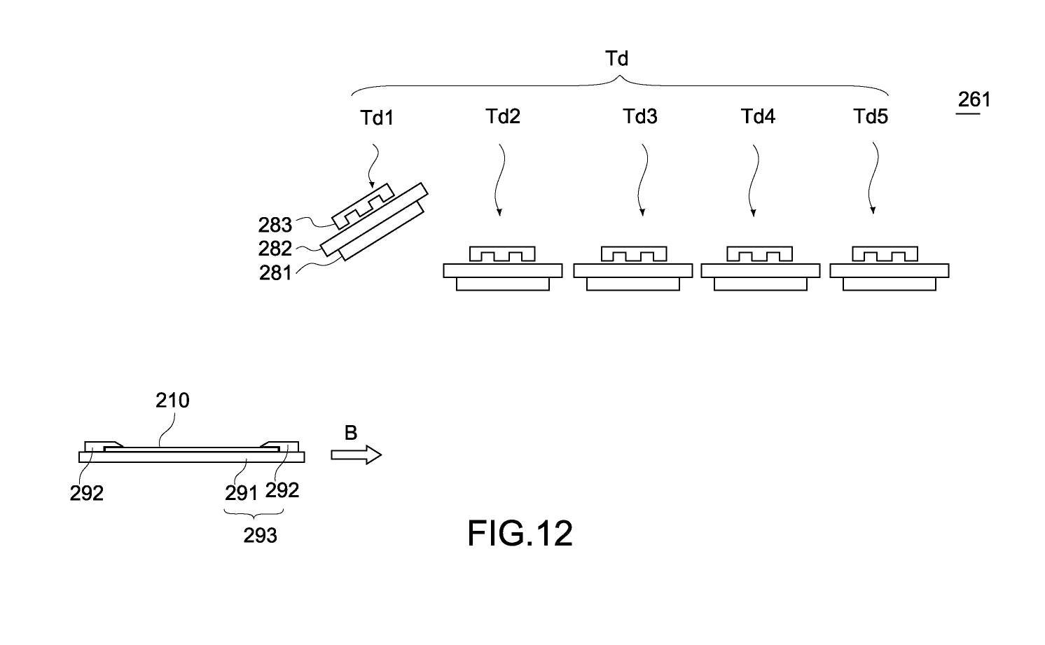

FIG. 12 is a schematic plan view showing a first sputtering chamber 261 according to the second embodiment.

Unlike the vacuum processing apparatus 100 according to the first embodiment, the vacuum processing apparatus according to this embodiment includes a target portion Td1 arranged at an angle to the conveying surface.

The first sputtering chamber 261 of the vacuum processing apparatus includes sputtering cathodes Td. The sputtering cathodes Td include target portions Td1, Td2, Td3, Td4, and Td5 each having the same configuration, which are arranged in series along the conveying direction B of a substrate 210. The target portion Td1 positioned on the most upstream side is arranged so that the target portion Td1 has a larger space from the conveying surface of the conveying mechanism in comparison with other target portions Td2, Td3, Td4, and Td5. Further, the target portion Td1 is arranged so as to be inclined with respect to the conveying surface so that the surface to be sputtered of the target portion Td1 is directed to the downstream side in the conveying direction, which is indicated by the arrow B in FIG. 12. The target portion Td1 may be fixed to the first sputtering chamber 261 in the inclined state, or may be attached to the first sputtering chamber 261 so that the target portion Td1 is allowed to be inclined.

Each of the sputtering cathodes Td includes a target plate 281, a backing plate 282, and a magnet 283.

The conveying mechanism conveys a supporting portion 293 so that the substrate 210 passes through the first position and the second position. The first position is a position in which only the sputtered particles obliquely emitted from the surface to be sputtered of the target portion Td1 arrive at the surface to be processed of the substrate 210. This position can be closer to the target portion Td1 in comparison with the first position according to the first embodiment because the target portion Td1 is inclined with respect to the conveying surface. The second position is a position in which the sputtered particles perpendicularly emitted from the surface to be sputtered of the target portion on the most downstream side (in this embodiment, the target portion Td5) arrive at the surface to be processed of the substrate 210. It should be noted that, in the second position, the sputtered particles obliquely emitted from the adjacent target position Td4 may arrive at the surface to be processed of the substrate 210. The conveying mechanism conveys the supporting portion 293 (the substrate 210) at least from the upstream side with respect to the first position to the downstream side with respect to the second position.

The sputtering by the vacuum processing apparatus configured in the above-mentioned manner will be described.

Similarly to the sputtering according to the first embodiment, due to the applied electrical field and magnetic field, the sputtering gas is converted into plasma.

The conveyance of the substrate 210 is started, and in the first position, the substrate 210 is subjected to the film formation using the sputtered particles obliquely emitted from the target portion Tdl. Here, the target portion Td1 is arranged so as to be inclined so that the surface to be sputtered is directed to the downstream side in the conveying direction B, and hence the sputtered particles obliquely emitted from the surface to be sputtered of the target portion Td1 are made incident on the surface to be processed in a direction perpendicular to the surface to be processed. Those sputtered particles are emitted obliquely from the surface to be sputtered of the target portion Td1, and hence the incident energy is small.

After that, similarly to the sputtering according to the first embodiment, the substrate 210 is conveyed, and the substrate 210 is subjected to the film formation using the sputtered particles respectively emitted from the target portions Td2, Td3, Td4, and Td5.

As described above, the incident angle of the sputtered particles with respect to the surface to be processed may affect the film properties of the formed thin-film. In particular, the sputtered particles emitted from the target portion Td1 are initially deposited on the surface to be processed on which no film is formed.

In the sputtering according to this embodiment, the target portion Td1 is inclined, and hence it is possible to make the obliquely emitted sputtered particles having the low incident energy incident on the substrate 210 in the direction perpendicular to the substrate 210, and to make the sputtered particles perpendicularly emitted from the target portion incident on the substrate 210 while ensuring a longer distance between the target portion and the substrate 210.

In the following, regarding the film formation using the sputtered particles emitted in the direction oblique to the surface to be sputtered of the target and using the sputtered particles emitted in the direction perpendicular to the surface to be sputtered of the target, differences of the film-forming speed and the damage received by the base layer will be described.

FIG. 6 is a view of a schematic configuration of the sputtering apparatus, which describes an experiment that the inventors of the present invention were performed. This sputtering apparatus included two sputtering cathodes T1 and T2, each of which included a target plate 11, a backing plate 12, and a magnet 13. The backing plate 12 of each of the sputtering cathodes T1 and T2 was connected to each electrode of an alternating-current power source 14. For the target plate 11, a target material of In—Ga—Zn—O composition was used.

A substrate having a surface on which a silicon oxide film was formed as the gate insulating film was arranged to be opposed to the sputtering cathodes T1 and T2. The distance (TS distance) between the sputtering cathode and the substrate was set to 260 mm. The center of the substrate was set to correspond to a middle point (point A) between the sputtering cathodes T1 and T2. The distance from this point A to the center (point B) of each of the target plate 11 was 100 mm. Oxygen gas at a predetermined flow rate was introduced into a vacuum chamber kept in depressurized argon atmosphere (flow rate 230 sccm, partial pressure 0.74 Pa), and each of the target plates 11 was sputtered with plasma 15 generated by applying alternating-current power (0.6 kW) between the sputtering cathodes T1 and T2.

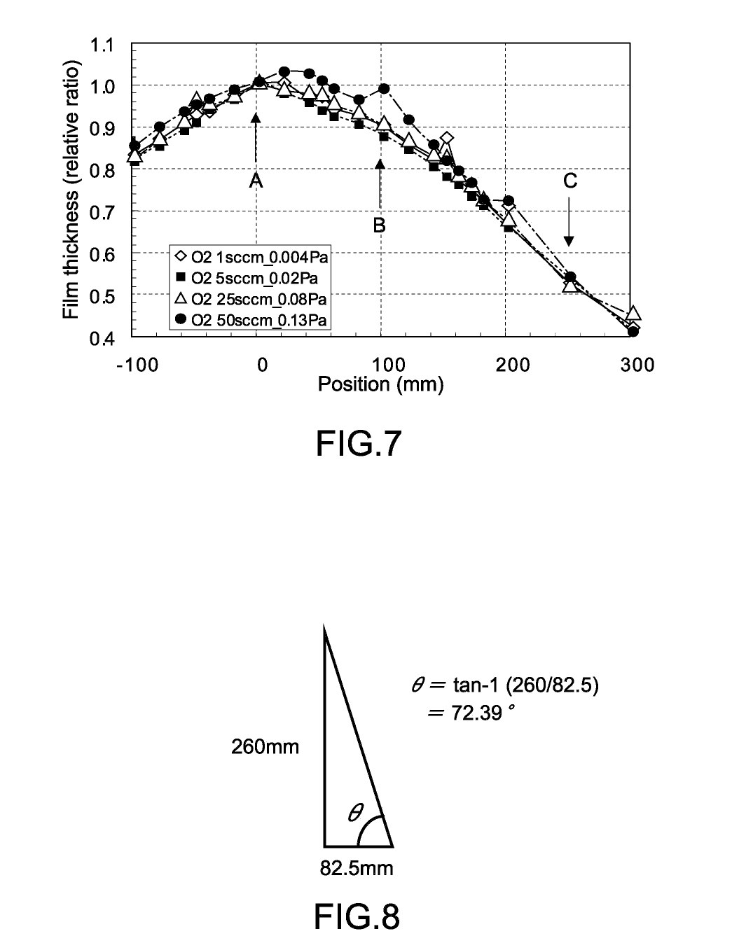

FIG. 7 shows measurement results of a film thickness at each position on the substrate, setting the point A as an original point. The film thickness at each point is represented as a relative ratio with respect to the film thickness of the point A set to 1. The temperature of the substrate was set to be equal to a room temperature. A point C indicates a position away from the point A by 250 mm. The distance from the outer periphery of the magnet 13 of the sputtering cathode T2 to the point C was 82.5 mm. In the drawing, a white diamond mark indicates a film thickness when the oxygen introduction amount was 1 sccm (partial pressure 0.004 Pa), a black square mark indicates a film thickness when the oxygen introduction amount was 5 sccm (partial pressure 0.02 Pa), a white triangle mark indicates a film thickness when the oxygen introduction amount was 25 sccm (partial pressure 0.08 Pa), and a black circle mark indicates a film thickness when the oxygen introduction amount was 50 sccm (partial pressure 0.14 Pa).

As shown in FIG. 7, the film thickness at the point A at which the sputtered particles emitted from the two sputtering cathodes T1 and T2 arrived was the largest. The film thickness was reduced while going away from the point A. The point C was a deposition region of the sputtered particles obliquely emitted from the sputtering cathode T2, and hence the film thickness at the point C was smaller than that at the deposition region (point B) of the sputtered particles perpendicularly emitted from the sputtering cathode T2. An incident angle θ of the sputtered particles at this point C was 72.39° as shown in FIG. 8.

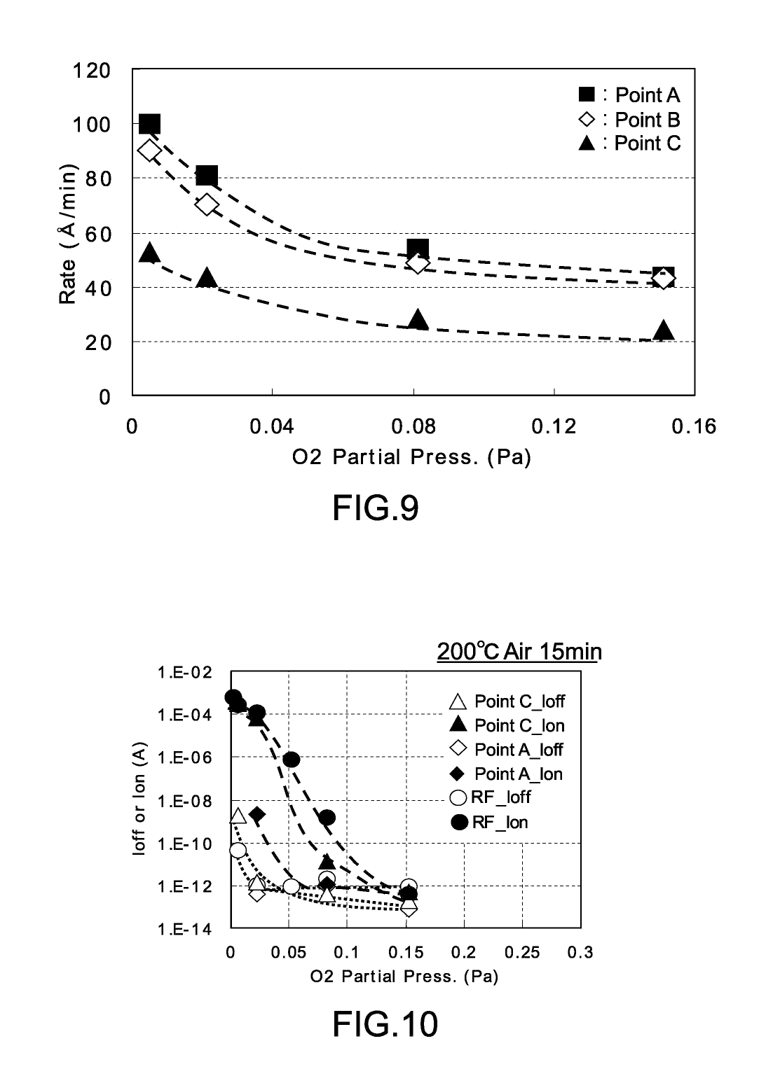

FIG. 9 is a view showing a relation between an introduced partial pressure and a film-forming rate, which was measured at each of the point A, the point B, and the point C. It was confirmed that irrespective of the film-forming position, as the oxygen partial pressure (oxygen introduction amount) becomes higher, the film-forming rate becomes lower.

At the point A and point C, thin-film transistors including the IGZO films, which were formed while varying the oxygen partial pressure, as the active layers were manufactured. By heating the sample of each transistor at 200° C. for 15 minutes in the atmosphere, the active layer was annealed. Then, with respect to each sample, ON-state current characteristics and OFF-state current characteristics were measured. The results are shown in FIG. 10. In the drawing, the vertical axis indicates ON-state current or OFF-state current, and the horizontal axis indicates an oxygen partial pressure during the formation of the IGZO film. As a reference, transistor properties of a sample including the IGZO film formed by an RF sputtering method using the passing-type film-forming method are shown together. In the drawing, a white triangle mark indicates an OFF-state current at the point C, a black triangle mark indicates an ON-state current at the point C, a white diamond mark indicates an OFF-state current at the point A, a black diamond mark indicates an ON-state current at the point A, a white circle mark indicates an OFF-state current of the reference sample, and a black circle mark indicates an ON-state current of the reference sample.

As will be clear from the results of FIG. 10, as the oxygen partial pressure becomes higher, the ON-state current decreases with respect to all of the samples. This is attributed to the fact that when oxygen concentration in the film becomes higher, the conductivity of the active layer becomes lower. Further, comparing the samples at the point A and the point C to each other, the sample at the point A has the ON-state current lower than that at the point C. This is attributed to the fact that during the formation of the active layer (IGZO film), a base film (gate insulating film) was greatly damaged due to collision of the sputtered particles, and hence the base film could not keep desired film quality. Further, the sample at the point C could obtain the ON-state current characteristics nearly equal to the ON-state current characteristics of the reference sample.

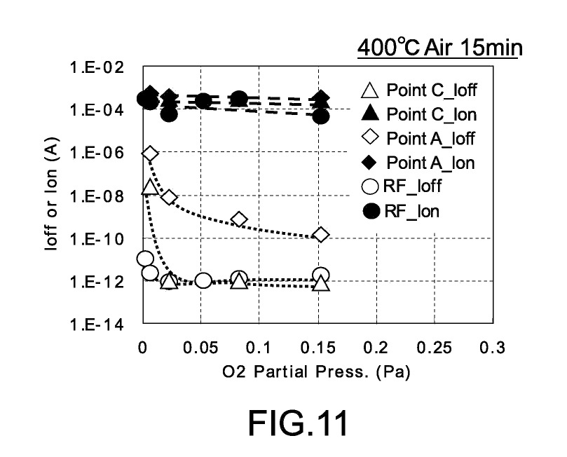

On the other hand, FIG. 11 shows results of an experiment in which the ON-state current characteristics and the OFF-state current characteristics of the thin-film transistor when the annealing condition of the active layer was set to be in the atmosphere, at 400° C., for 15 minutes were measured. Under this annealing condition, significant differences between the ON-state current characteristics of respective samples were not observed. However, it was confirmed that in regard to the OFF-state current characteristics, the sample at the point A is higher than each of the sample at the point C and the reference sample. This is attributed to the fact that during the formation of the active layer, the base film was greatly damaged due to collision of the sputtered particles, and hence the base film lost a desired insulating property.

Further, it was confirmed that by setting the annealing temperature to be high, it is possible to obtain high ON-state current characteristics without being affected by the oxygen partial pressure.

As will be clear from the above-mentioned results, in such a manner that when the active layer of the thin-film transistor is formed by sputtering, an initial layer of the thin-film is formed of the sputtered particles incident on the substrate in a direction oblique to the substrate, it is possible to obtain excellent transistor properties, that is, high ON-state current and low OFF-state current. Further, it is possible to stably manufacture the active layer of In—Ga—Zn—O-based composition, which has desired transistor properties.

Although the embodiments of the present invention have been described, it is needless to say that the present invention is not limited thereto and various modifications can be made based on the technical conception of the present invention.

Although in each of the above-mentioned embodiments, the first target is one target portion, the present invention is not limited thereto, and the first target may be composed of a plurality of target portions. Further, the first target may be composed of a plurality of target portions arranged so that the plurality of target portions have gradually smaller spaces with respect to the conveying surface along the conveying direction of the substrate.

Further, although in each of the above-mentioned embodiments, the description has been made by exemplifying the manufacturing method for the thin-film transistor including the IGZO film as the active layer, the present invention is also applicable in a case where a film made of another film-forming material such as a metal material is formed by sputtering.

### DESCRIPTION OF SYMBOLS

10 substrate
11 target
13 magnet
61 first sputtering chamber
71 holding mechanism
81 target plate
83 magnet
93 supporting portion
100 vacuum processing apparatus
210 substrate
261 first sputtering chamber
281 target plate
283 magnet
293 supporting portion
Tc sputtering cathode
Td sputtering cathode

1. A sputtering apparatus for forming a thin-film on a surface to be processed of a substrate, comprising:
a vacuum chamber capable of keeping a vacuum state;
a supporting portion, which is arranged in an inside of the vacuum chamber, and supports the substrate;
a conveying mechanism, which is arranged in the inside of the vacuum chamber, and linearly conveys the supporting portion along a conveying surface parallel to the surface to be processed;
a first target opposed to the conveying surface with a first space therebetween;
a second target, which is arranged on a downstream side in a conveying direction of the substrate with respect to the first target, and is opposed to the conveying surface with a second space smaller than the first space therebetween; and
a sputtering means for sputtering the first target and the second target.

2. The sputtering apparatus according to claim 1, wherein
the conveying mechanism conveys the substrate while sequentially passing through a fist position and a second position,
the first position is a position in which only sputtered particles obliquely emitted from the first target arrive at the surface to be processed, and
the second position is a position in which sputtered particles perpendicularly emitted from the second target arrive at the surface to be processed.

3. The sputtering apparatus according to claim 2, wherein
a surface to be sputtered of the first target is arranged in parallel to the conveying surface.

4. The sputtering apparatus according to claim 2, wherein
a surface to be sputtered of the first target is arranged on a side of the second position.

5. A thin-film forming method, comprising:
arranging a substrate, which has a surface to be processed, in a vacuum chamber provided with a first target opposed to a conveying surface of the substrate with a first space therebetween and with a second target opposed to the conveying surface of the substrate with a second space smaller than the first space therebetween;
conveying the substrate from a first position to a second position;
subjecting, in the first position, the surface to be processed to film formation using only sputtered particles obliquely emitted by sputtering the first target; and
subjecting, in the second position, the surface to be processed to film formation using sputtered particles perpendicularly emitted by sputtering the second target.

6. A manufacturing method for a field effect transistor, comprising:
forming a gate insulating film on a substrate;
arranging a substrate in a vacuum chamber provided with a first target, which has In—Ga—Zn—O-based composition and is opposed to a conveying surface of the substrate with a first space therebetween, and with a second target, which has In—Ga—Zn—O-based composition and is opposed to the conveying surface of the substrate with a second space smaller than the first space therebetween;
conveying the substrate from a first position to a second position; and
subjecting, in the first position, the surface to be processed to film formation using only sputtered particles obliquely emitted by sputtering the first target and subjecting, in the second position, the surface to be processed to film formation using sputtered particles perpendicularly emitted by sputtering the second target, to thereby form an active layer.
